(19) United States
(12) Patent Application Publication
(10) Pub. No.: US 2009/0020313 A1
(43) Pub. Date: Jan. 22, 2009

(54) CIRCUIT LOGIC EMBEDDED WITHIN IC PROTECTIVE LAYER

(75) Inventors: Yves LEDUC, Roquefort-les-Pins (FR); Nathalie MESSINA, Nice (FR); Kelly J. TAYLOR, Allen, TX (US); Louis N. HUTTER, Plano, TX (US); Jeffrey P. SMITH, Plano, TX (US); Byron L. WILLIAMS, Plano, TX (US); Abha R. SINGH, Fairview, TX (US); Scott R. SUMMERFELT, Garland, TX (US); Daniel L. CALLAHAN, Dallas, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/781,133

(22) Filed: Jul. 20, 2007

(51) Int. Cl. H05K 3/00; H05K 1/00

(52) U.S. Cl. 174/250; 29/829

(57) ABSTRACT

A system comprising a first layer comprising one or more metal sub-layers and a protective overcoat (PO) layer adjacent to the first layer. The PO layer is adapted to protect the first layer, and a circuit logic is at least partially embedded within the PO layer. The circuit logic couples to one of the metal sub-layers.

### CROSS-REFERENCE TO RELATED APPLICATION

The present application contains subject matter related to EP Application No. 05291924.8, filed on Sep. 16, 2005 and incorporated herein by reference.

### BACKGROUND

Integrated circuits (ICs) generally are mounted on circuit boards (e.g., motherboards). The ICs comprise multiple pins which couple to electrical pathways, such as traces, that are on the circuit boards. In this way, an IC may interact with other circuitry on a circuit board by transferring electrical signals to and receiving signals from such circuitry.

In some applications, it is necessary to include additional circuitry, such as decoupling capacitors, on a circuit board having an IC. Such components are coupled to the IC and are used to perform electrical functions that the IC does not perform or is not capable of performing. Including capacitors and other circuitry on the circuit board in this way consumes substantial amounts of real estate, resulting in increased production costs.

### SUMMARY

Accordingly, there are disclosed herein techniques by which circuitry (e.g., capacitors) is fabricated within an integrated circuit (IC). Illustrative embodiments include a system comprising a first layer comprising one or more metal sub-layers and a protective overcoat (PO) layer adjacent to the first layer. The PO layer is adapted to protect the first layer. A circuit logic is at least partially embedded within the PO layer. The circuit logic couples to one of the metal sub-layers.

Other illustrative embodiments include a method that comprises producing a circuit logic having a conductive layer, a substrate adjacent to one surface of the conductive layer, and a protective layer adjacent to another surface of the conductive layer. The surface adjacent the conductive layer is located opposite the surface of the conductive layer adjacent the substrate. The protective layer is adapted to protect the conductive layer. The method further comprises at least partially embedding a circuit component within the protecting layer. The circuit component is coupled to the conductive layer.

Yet other illustrative embodiments include a method that comprises creating orifices within a protective overcoat layer of an integrated circuit, where the protective overcoat layer is adapted to protect the integrated circuit. The method also comprises depositing a first electrode layer abutting the protective overcoat layer such that at least part of the first electrode layer is embedded within the protective overcoat layer. The method also comprises depositing a dielectric layer abutting the first electrode layer such that at least part of the dielectric layer is embedded within the protective overcoat layer. The method further comprises depositing a second electrode layer abutting the dielectric layer such that at least part of the second electrode layer is embedded within the protective overcoat layer.

### BRIEF DESCRIPTION OF THE DRAWINGS

For a detailed description of exemplary embodiments of the invention, reference will now be made to the accompanying drawings in which:

FIG. 1 shows a system in accordance with embodiments of the invention;

FIGS. 2a-2o illustrate an IC assembly process, in accordance with preferred embodiments of the invention; and

FIG. 3 shows a flow diagram of a method associated with FIGS. 2a-2o, in accordance with embodiments of the invention.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical connection. Thus, if a first device couples to a second device, that connection may be through a direct electrical connection, or through an indirect electrical connection via other devices and connections. The term “connection” refers to any path via which a signal may pass. For example, the term “connection” includes, without limitation, wires, traces and other types of electrical conductors, optical devices, etc. Further, all measurements and physical dimensions provided herein are illustrative of various embodiments and do not limit the scope of this disclosure.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

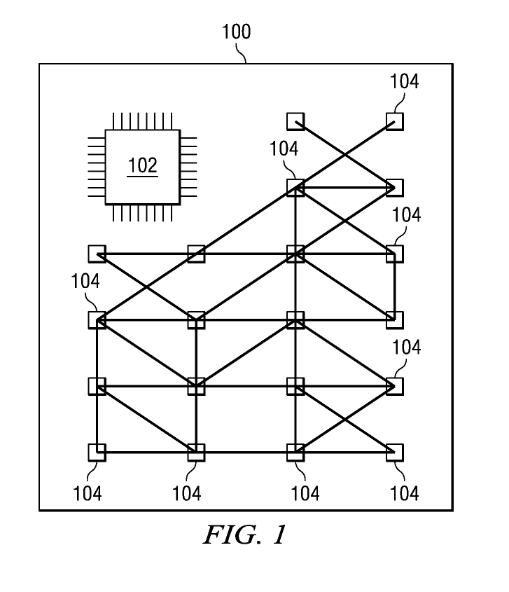

Described herein are techniques by which capacitors and other types of circuit logic may be embedded within an integrated circuit (IC), thereby freeing up circuit board space which would otherwise have been occupied by the circuit logic. FIG. 1 shows a circuit board 100 comprising an IC 102 and various circuit logic 104. In some embodiments, the techniques described herein may be used to embed circuit logic within the IC 102 with the IC 102 disposed on the circuit board 100. In other embodiments, the techniques disclosed herein may be used to embed circuit logic within the IC 102 before the IC 102 is coupled to the circuit board 100. The IC 102 may be housed within any type of device—for example, a mobile communication device such as a cell phone, a personal digital assistant (PDA), a laptop computer, a wireless media player such as the iPHONE®, etc.

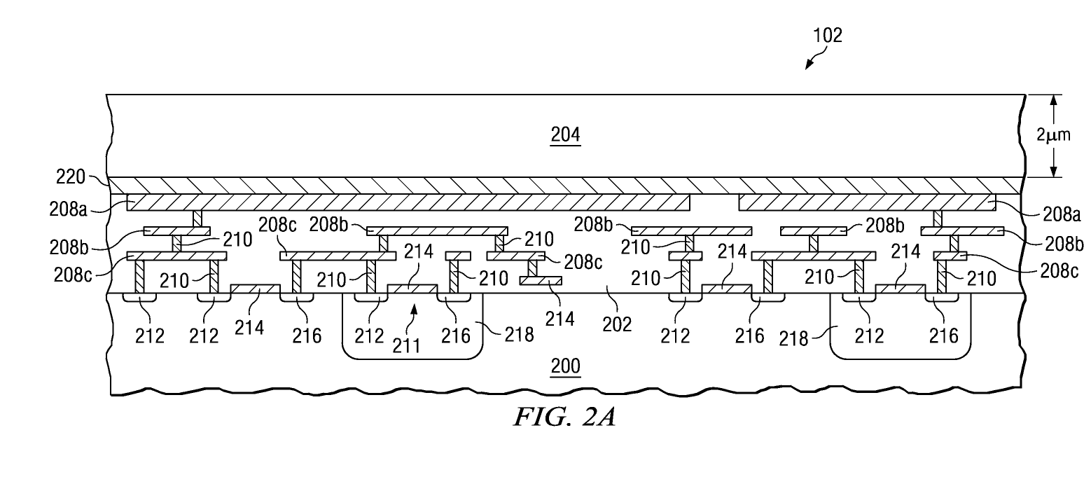

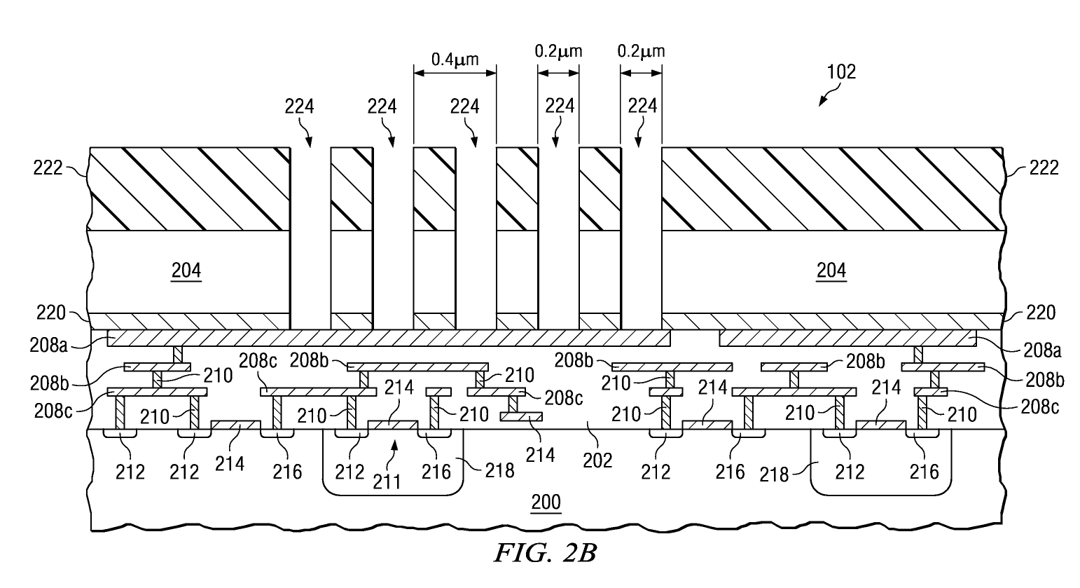

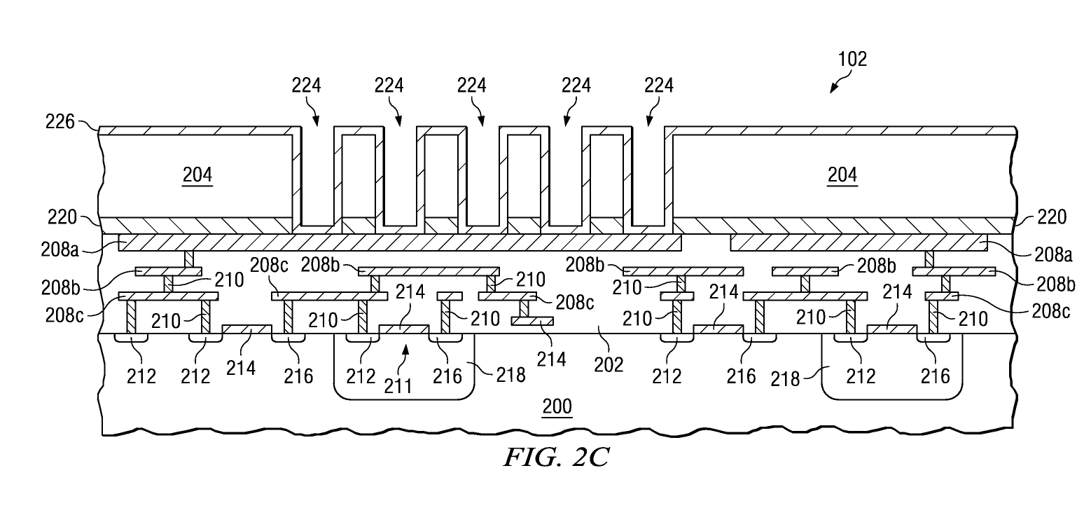

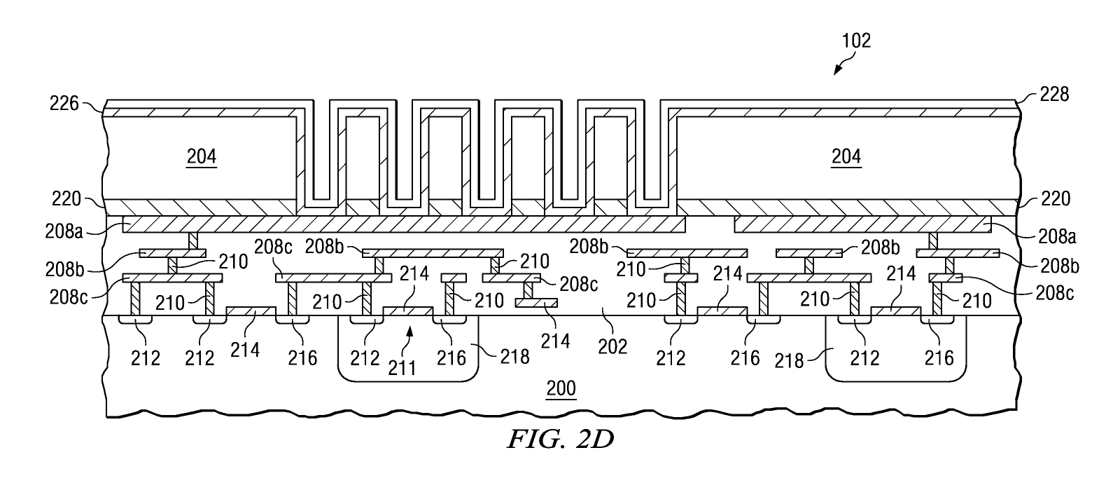

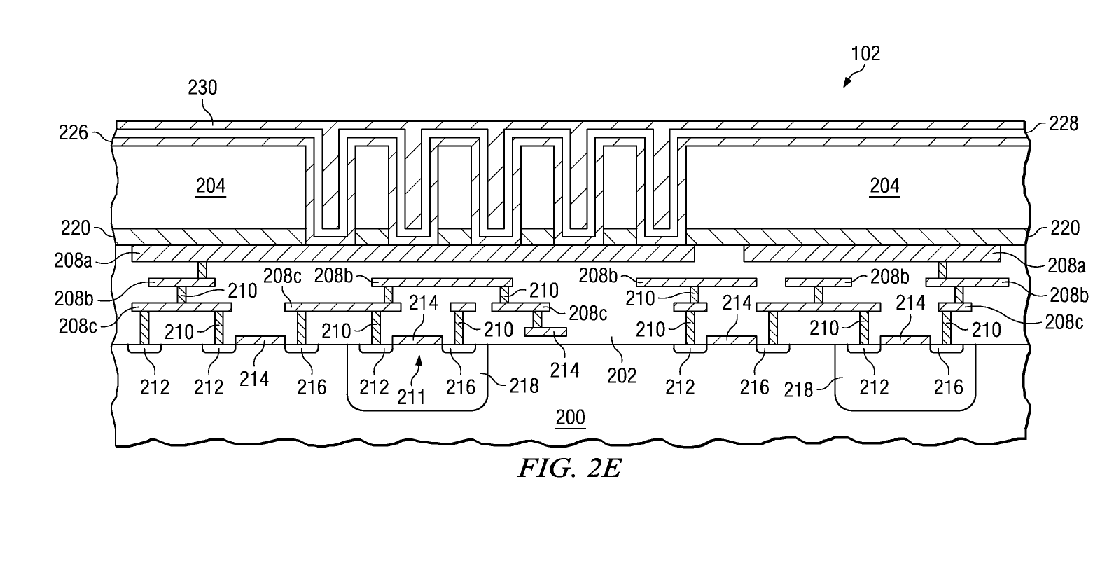

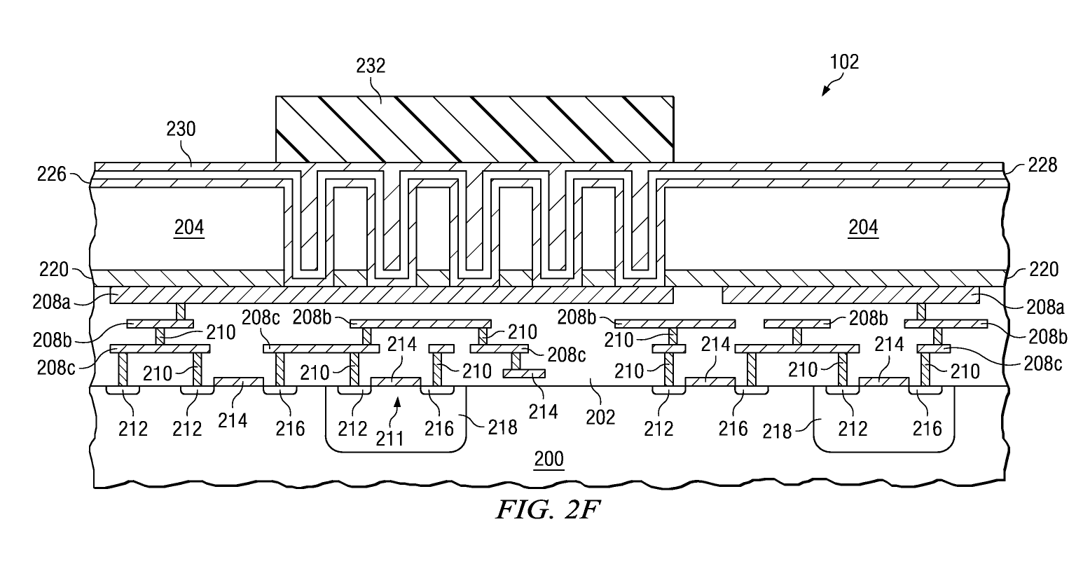

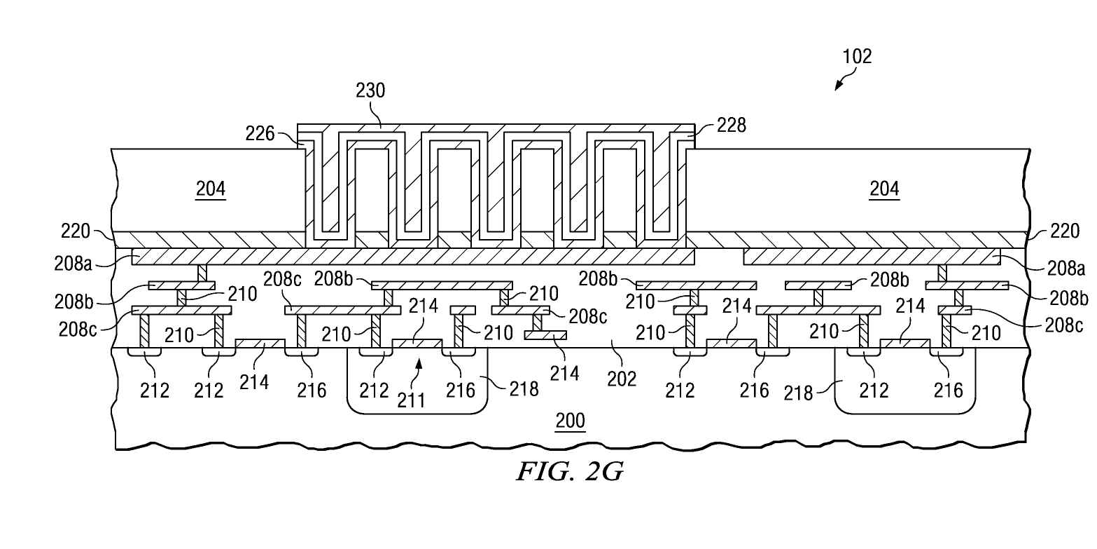

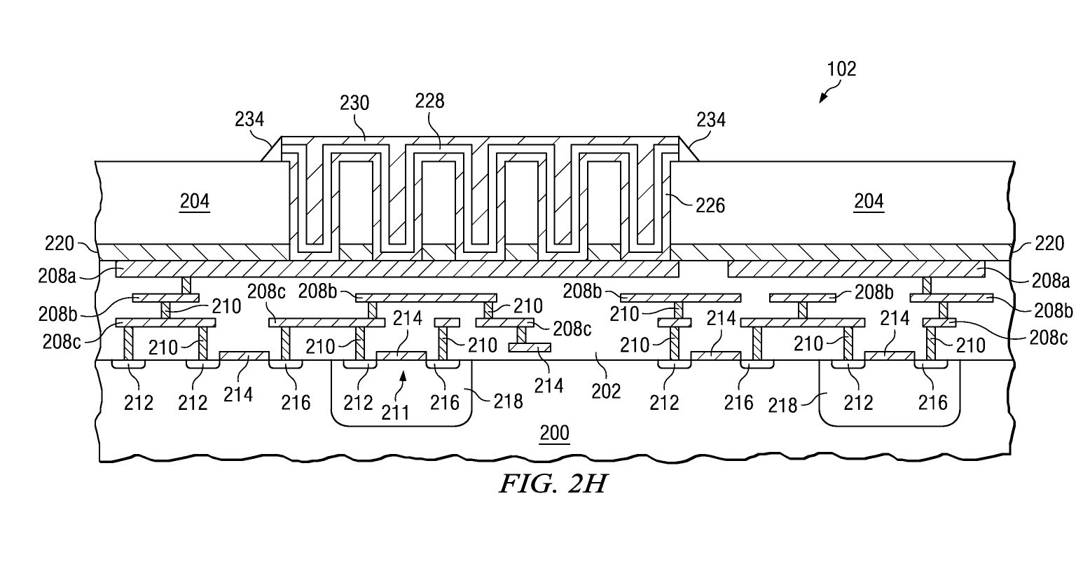

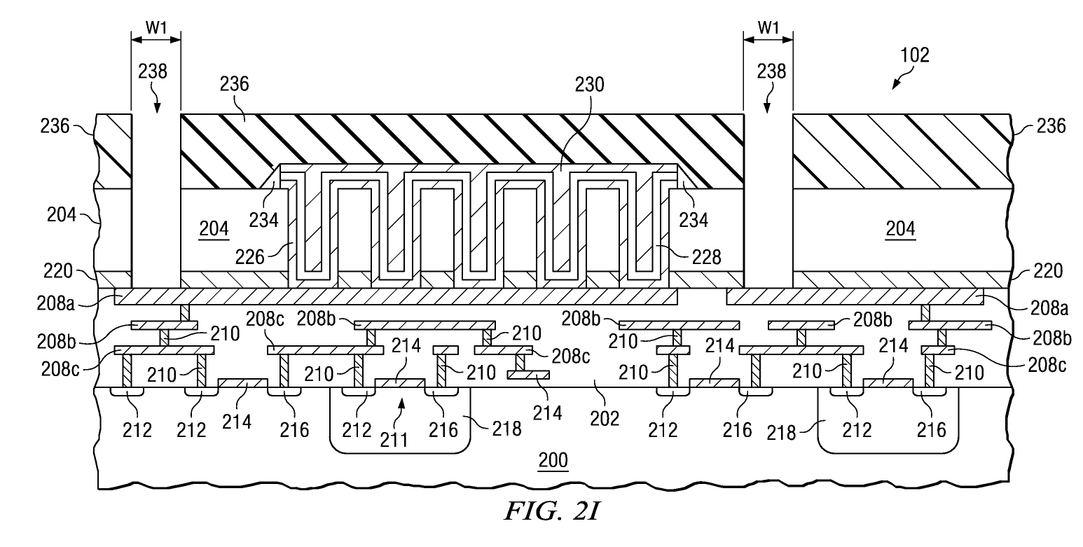

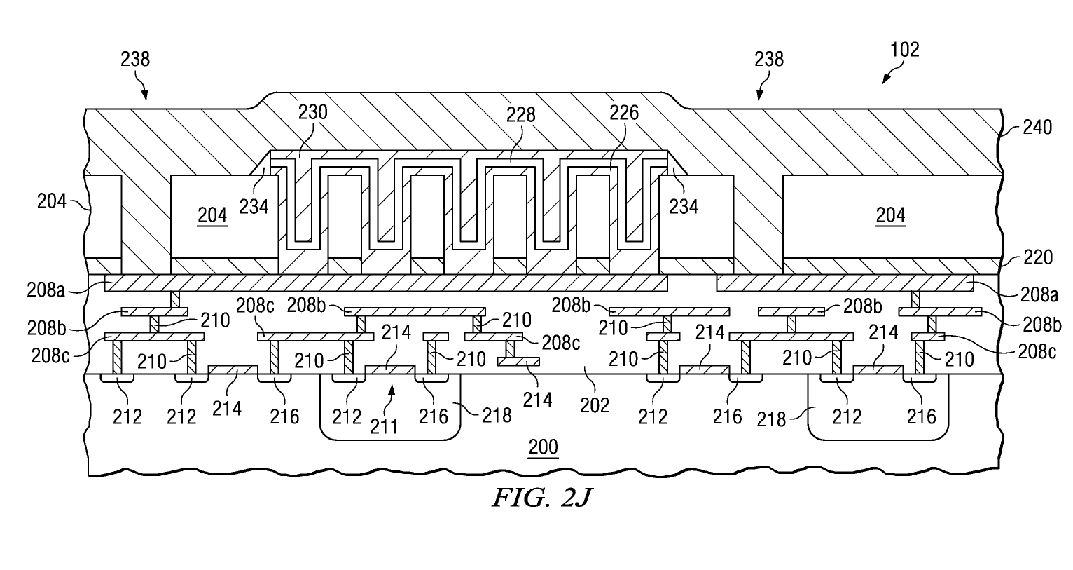

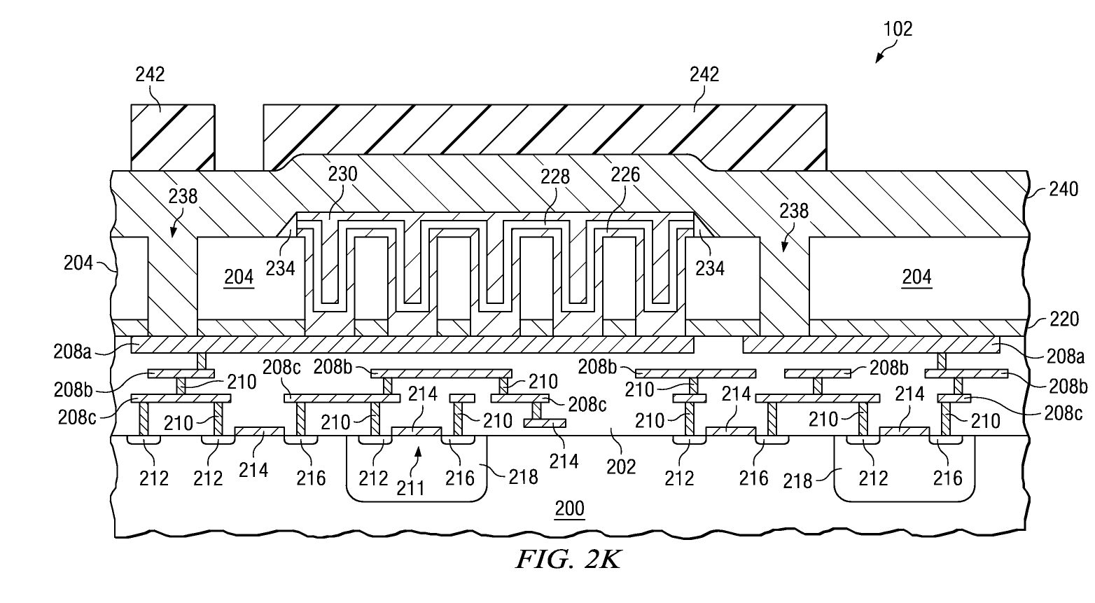

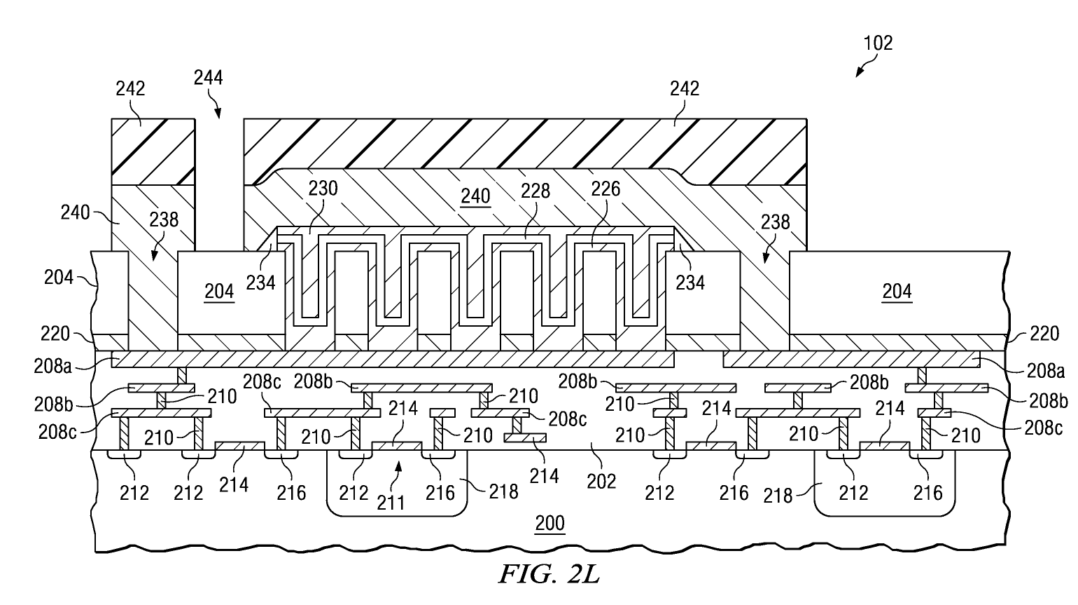

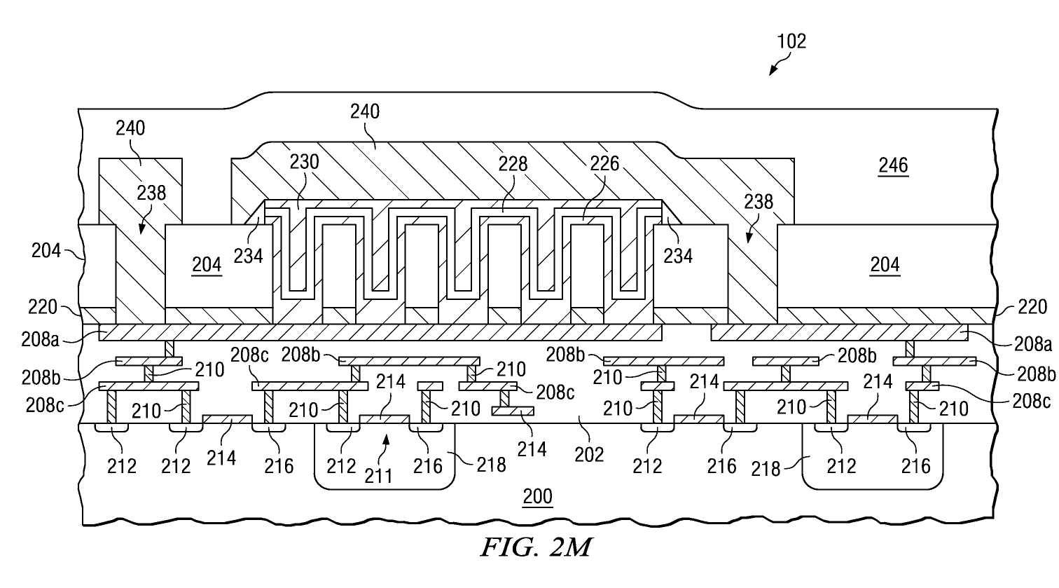

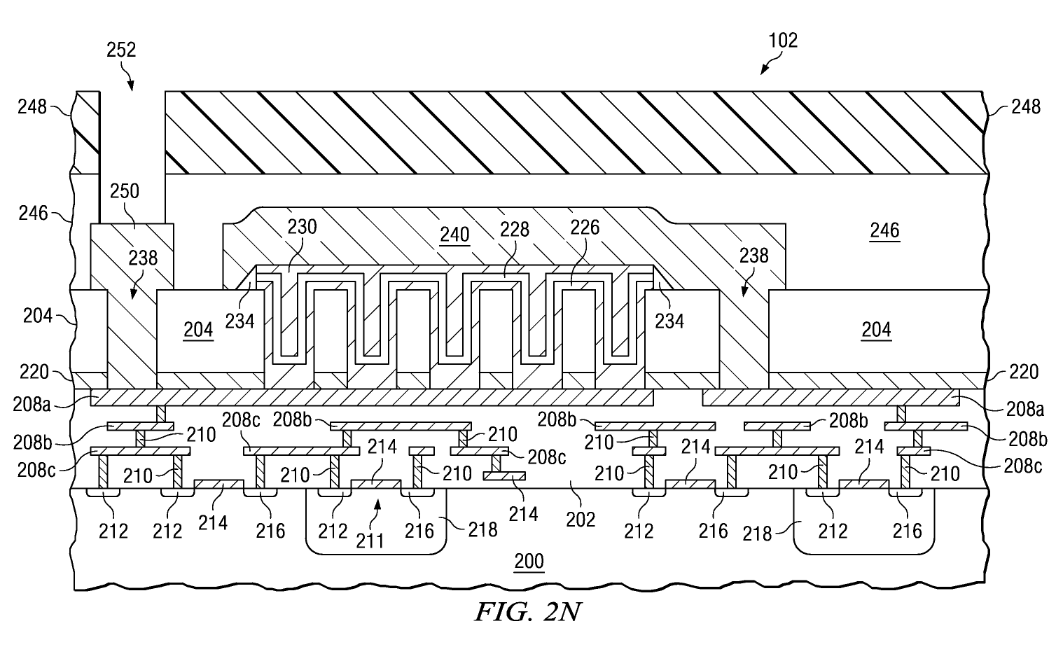

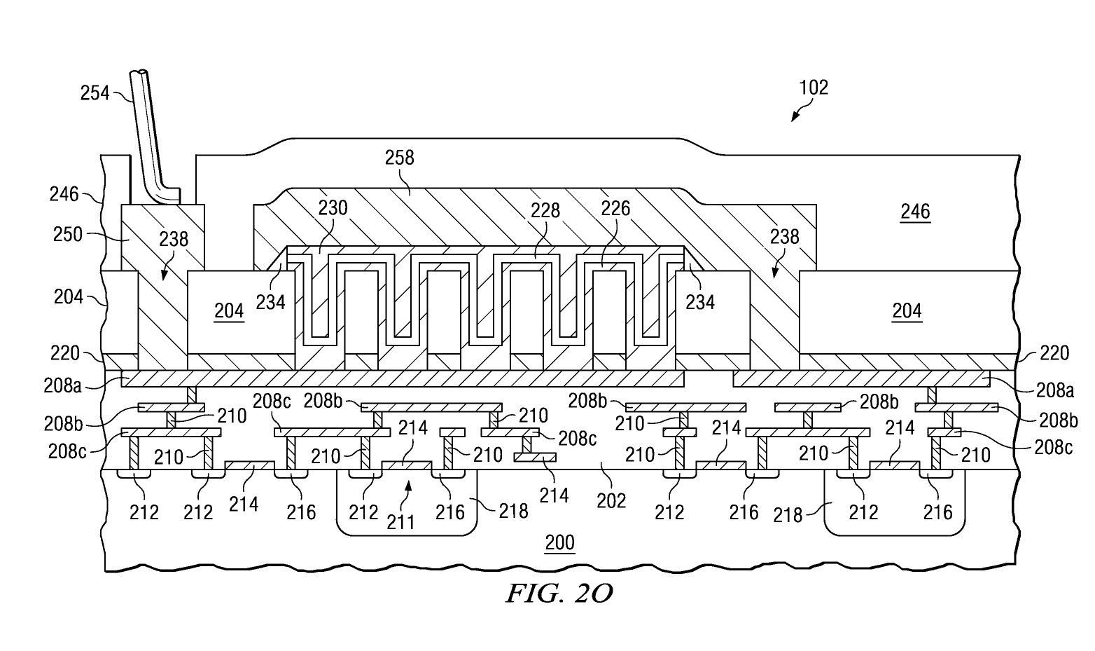

FIGS. 2a-2o show an illustrative process used to embed circuit logic, such as a capacitor, within an IC 102. Referring to FIG. 2a, there is shown a cross-sectional view of such an IC 102. The IC 102 comprises multiple layers. Specifically, the IC 102 comprises a substrate layer 200, a metal layer 202 and a protective overcoat layer 204. The substrate layer 200 preferably comprises silicon, although other suitable materials fall within the scope of this disclosure. In some embodiments, the substrate layer 200 has a thickness of 250-800 micrometers. The metal layer 202 comprises a plurality of sub-layers 208a, 208b and 208c. Although three sub-layers are shown, any suitable numbers of sub-layers may be included. The sub-layers 208 comprise an electrically conductive substance (e.g., metal) by which electrical signals are transferred. Each sub-layer 208 is electrically coupled to another sub-layer 208 using vias 210, which also are electrically conductive substances (e.g., metal). Using the vias 210, the bottom sub-layer 208c couples to field effect transistors (FETs) 211 having sources/drains 212, gates 214 and/or drains/sources 216. If a reference 212 refers to a source, then reference 216 refers to a drain. Likewise, if reference 212 refers to a drain, then reference 216 refers to a source. Sources, drains and combinations thereof may couple to each other by way of wells 218, such as p-wells, n-wells, etc. In some embodiments, the wells and at least portions of the transistors are located in the substrate layer 200. In some embodiments, the thickness of the metal layer 202 is 1-5 micrometers. A material such as tungsten or copper may be used between the sub-layers 208.

The protective overcoat (PO) layer 204 protects the metal layer 202 from debris, etc. to preserve the functional integrity of the metal layer 202. The PO layer 204 may comprise any suitable protective material, such as silicon oxynitride and/or silicon nitride. The bottom of the PO layer 204 (i.e., abutting the metal layer 202) may be a sub-layer 220 composed of any suitable type of metal. In some embodiments, the thickness of the PO layer 204 may be approximately 2 micrometers.

FIG. 2b shows a modified version of the IC 102 shown in FIG. 2a. Specifically, as shown in FIG. 2b, an etch resist layer 222 has been deposited abutting the PO layer 204. In at least some embodiments, the thickness of the etch resist layer 222 is approximately 0.69 micrometers. The etch resist layer may be deposited using any suitable deposition technique. Further, as shown in FIG. 2b, the etch resist layer 222 has been etched to form a plurality of orifices 224. The orifices 224 preferably extend through the etch resist layer 222 and through the PO layer 204. In some embodiments, the width (or diameter) of each orifice 224 is 0.2 micrometers. In some embodiments, the distance between each orifice 224 is 0.2 micrometers. The orifices 224 may be created using any suitable etch process.

FIG. 2c shows a modified version of the IC 102 shown in FIG. 2b. Specifically, as shown in FIG. 2c, the resist layer 222 has been removed using, for example, a resist cleanup process. Further, as shown in FIG. 2c, an electrode layer 226 (comprising any suitable material, such as TaN, TiN, etc.) has been deposited abutting the PO layer 204. In some embodiments, the thickness of the electrode layer 226 is approximately 500 Angstroms. Further, any suitable process may be used to deposit the electrode layer 226 onto the IC 102, including physical vapor deposition (PVD), chemical vapor deposition (CVD), atomic layer deposition (ALD), etc.

FIG. 2d shows a modified version of the IC 102 shown in FIG. 2c. Specifically, as shown in FIG. 2d, a dielectric layer 228 (e.g., a Hi-K dielectric) has been deposited abutting the electrode layer 226. The dielectric layer 228 comprises any suitable material or combination of materials, such as aluminum oxide and hafnium oxide. In some embodiments, the dielectric layer 228 is composed of a layer of halfnium oxide sandwiched between two layers of aluminum oxide (not specifically shown) The dielectric layer 228 may be deposited using any suitable process, preferably an ALD process. The preferred thickness of the dielectric layer 228 is approximately 150-300 Angstroms.

FIG. 2e shows a modified version of the IC 102 shown in FIG. 2d. Specifically, as shown in FIG. 2e, another electrode layer 230 has been deposited abutting the dielectric layer 228. The electrode layer 230 comprises any suitable material, such as TaN, TiN, etc. In some embodiments, the thickness of the electrode layer 230 is approximately 600 Angstroms. Preferably, deposition of the electrode layer 230 causes some or all orifices 224 to be fully filled, as shown in FIG. 2e. Accordingly, in such embodiments, the electrode layer 230 preferably forms a substantially flat surface atop the IC 102, as shown in FIG. 2e. The scope of this disclosure is not limited to deposition of electrode layers which fully mirror the layer 230 shown in FIG. 2e and described herein. Other electrode layer arrangements are possible.

FIG. 2f shows a modified version of the IC 102 shown in FIG. 2e. Specifically, as shown in FIG. 2f, an etch resist layer 232 is deposited abutting the electrode layer 230. Preferably, the etch resist layer 232 is directly “above” at least some of the orifices 224, as shown in FIG. 2f. Preferably, the etch resist layer 232 is not present directly “above” at least some portions of the PO layer 204. In some embodiments, the etch resist layer 232 has a thickness of 1 micrometer.

FIG. 2g shows a modified version of the IC 102 shown in FIG. 2f. Specifically, as shown in FIG. 2g, an etching process is performed on the IC 102 such that portions of the electrode layer 230 not abutting the etch resist layer 232 are etched away. The etching process is also performed such that portions of the dielectric layer 228 abutting portions of the electrode layer 230 etched away also are etched away. The etching process is also performed such that portions of the electrode layer 226 abutting portions of the dielectric layer 228 etched away also are etched away, as shown in FIG. 2g. Any suitable etch process may be used. Also as shown in FIG. 2g, the etch resist layer 232 is removed (i.e., after the etching process is complete) using, for example, solvent and ash.

FIG. 2h shows a modified version of the IC 102 shown in FIG. 2g. Specifically, as shown in FIG. 2h, an insulative sidewall 234 is added to the perimeter of the electrode layers 226 and 230 and dielectric layer 228. The sidewall 234 preferably comprises a nitride material and has a thickness (e.g., 1000-2000 Angstroms) approximately the same thickness as the combination of the electrode and dielectric layers, as shown in FIG. 2h. The sidewall 234 is deposited using any suitable technique, preferably a plasma technique. A purpose of the sidewall 234 is to create electrical isolation between the top and bottom electrodes 226 and 230. Although the cross-sectional shape of the sidewall 234 is shown to be triangular, the scope of this disclosure is not limited to a sidewall 234 of any particular shape or size.

FIG. 2i shows a modified version of the IC 102 shown in FIG. 2h. Specifically, as shown in FIG. 2i, an etch resist 236 is deposited using any suitable technique, such as the 2.0 deposition technique. An etch is performed to form multiple orifices 238, each of which preferably extends through the etch resist 236 and the PO layer 204 to the sub-layer 208a, as shown in FIG. 2i. The width W1 of the orifices 238 preferably is 0.2 micrometers. Although only two orifices 238 are shown, an IC 102 may have any suitable number of such orifices.

FIG. 2j shows a modified version of the IC 102 shown in FIG. 2i. Specifically, as shown in FIG. 2j, an outer metal layer 240 is deposited using any suitable deposition process, preferably a PVD process. The metal layer 240 has a preferred thickness of approximately 1 micron, although any suitable thickness may be used. Further, the metal layer 240 may comprise any suitable material, such as Ti, TiN, Al, TiN, etc. In some embodiments, the metal layer 240 comprises a plurality of metals. For example, in some such embodiments, the metal layer 240 may comprise a first sub-layer which may be a thin barrier layer, and a second sub-layer which may be a thicker signal or power metal layer. The metal layer 240 preferably fills the orifices 238.

FIG. 2k shows a modified version of the IC 102 shown in FIG. 2j. Specifically, as shown in FIG. 2k, an etch resist 242 is deposited onto the metal layer 240 using any suitable deposition process. A spin coat deposition process is preferred. The preferred thickness of the etch resist 242 is approximately 2.2 micrometers. The etch resist 242 preferably is deposited in a pattern as shown in FIG. 2k. Specifically, portions of the metal layer 240 which are to be protected from etching abut the etch resist 242. Portions of the metal layer which are to be etched away do not abut the etch resist 242.

FIG. 2l shows a modified version of the IC 102 shown in FIG. 2k. Specifically, as shown in FIG. 2l, an etching process is performed to create an orifice 244 which extends through the metal layer 240 and also to etch away other portions of the metal layer 240 not protected by the etch resist 242.

FIG. 2m shows a modified version of the IC 102 shown in FIG. 2l. Specifically, as shown in FIG. 2m, the etch resist 242 is removed (e.g., using a solvent and an ash) and a secondary PO layer 246 is deposited abutting the outer metal layer 240 and the PO layer 204. The PO layer 246 may be deposited as desired, but preferably a plasma oxide deposition process is used. In preferred embodiments, the PO layer 246 comprises SiON, SiN or a combination thereof, although the scope of this disclosure is not limited as such. In some such embodiments, the PO layer 246 comprises a 4 kilo-Angstrom layer of SiON abutting a 4 kilo-Angstrom layer of SiN. The PO layer 246 protects the metal layer 240 from debris, etc. to preserve the functional integrity of the metal layer.

FIG. 2n shows a modified version of the IC 102 shown in FIG. 2m. Specifically, as shown in FIG. 2n, an etch resist 248 is deposited onto the PO layer 246. The etch resist 248 may be deposited using any suitable deposition technique, such as the spin coat technique. Other deposition techniques also may be used. In preferred embodiments, the etch resist 248 is deposited such that substantially all portions of the PO layer 246 are protected except for the portion of the PO layer 246 abutting at least some of the metal component 250. The IC 102 is then etched, thereby creating an orifice 252, as shown.

FIG. 2o shows a modified version of the IC 102 shown in FIG. 2n. Specifically, as shown in FIG. 2o, the etch resist 248 is removed. Once the etch resist 248 is removed, the IC 102 is substantially complete, and a wirebond 254 (or other suitable electrical connection) may be coupled to the metal component 250. Although FIG. 2o shows a wirebond coupling, in some embodiments, the steps of FIGS. 2a-2o may be modified to produce an IC 102 that is able to form different types of electrical connections. For example, in some embodiments, the metal component 250 may be extended such that the metal component 250 is adapted to couple to a bondpad (not specifically shown) instead of a wirebond. All such modifications are encompassed within the scope of this disclosure.

In operation, the IC 102 shown in FIG. 2o performs as follows. The IC 102 is coupled to a printed circuit board, such as a motherboard, using the wirebond(s) 254, bondpads, or other suitable electrical connection devices. In this way, electrical coupling between the board and the IC 102 is facilitated. A signal received via wirebond 254 may be provided to the metal component 250. The signal may pass from the metal component 250 to the metal sub-layers 208a, 208b and 208c by means of the vias 210. The metal sub-layers 208a, 208b and 208c, as well as the gates, drains and sources disposed within the substrate 200, process the signal as the IC 102 was designed to process such received signals (i.e., by performing one or more tasks with the signal). Capacitance is available to the metal sub-layers by means of the metal sub-layer 208a marked as component 256 and the metal layer 240 marked as component 258. Specifically, an electrical signal may pass through components 256 and 258 to the electrode 226, dielectric 228 and electrode 230. The electrodes 226 and 230 and dielectric 228 together form a capacitor which is at least partially embedded within PO layer 204. The electrodes 226 and 230, along with the dielectric 228, provide capacitance to the IC 102. More specifically, a charge is built up and stored between the electrodes 226 and 230 due in part to the presence of the dielectric 228. The permittivity K of the dielectric 228 may be chosen as desired to adjust the capacitance of the capacitor. In preferred embodiments, a substantially high K dielectric is used.

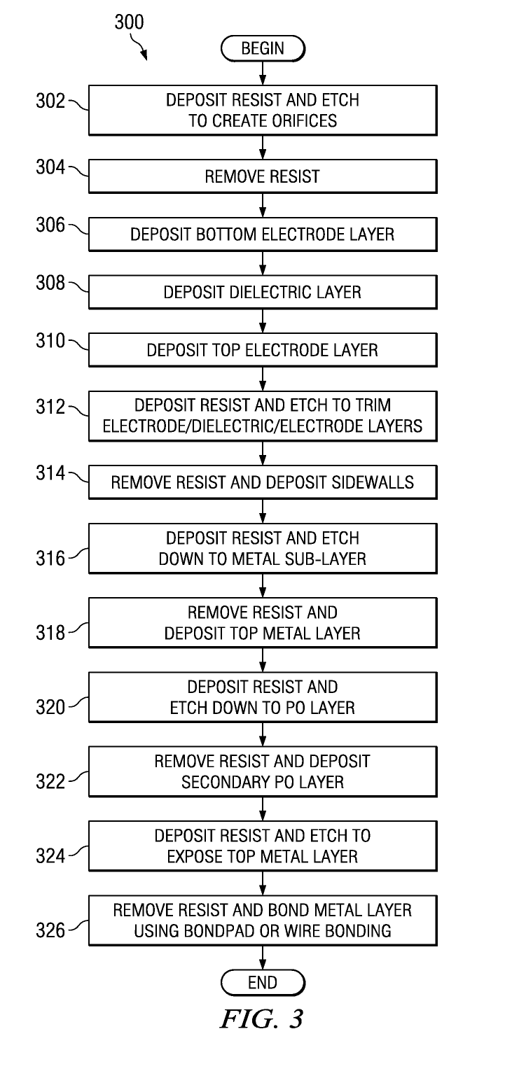

FIG. 3 shows a flow diagram of a method 300 by which an IC 102 such as that shown in FIG. 2o may be assembled. The method 300 begins by depositing resist and etch to create orifices (block 302), as shown in FIG. 2b. The method 300 continues by removing the resist (block 304) and depositing a bottom electrode layer (block 306). The method 300 continues by depositing a dielectric layer abutting the bottom electrode layer (block 308) and further by depositing a top electrode layer abutting the dielectric layer (block 310). The method 300 continues by depositing resist and etching to trim the electrode and dielectric layers (block 312).

The method 300 still further continues by removing the resist and depositing and etching sidewalls (block 314), depositing resist and etching down to a metal sub-layer (block 316), removing the resist and depositing an outer metal layer (block 318). The method 300 further comprises depositing resist and etching down to a PO layer (block 320), removing the resist and depositing a secondary PO layer (block 322). The method 300 then comprises depositing resist and etching to expose the outer metal layer (block 320). The method 300 also comprises removing the resist and coupling an electrical connection to the outer metal layer (block 326) using, for example, a wirebond or bondpad. The steps of the method 300 may be modified and re-arranged as desired. Some steps may be performed concurrently.

The embodiments disclosed herein have primarily been described in context of the fabrication of one or more capacitors within the IC 102. However, the embodiments may be modified for the fabrication of any type of circuit logic within the IC 102. Fabrication of capacitors, resistors, inductors and other such passive components within the IC 102 as described above are all included within the scope of this disclosure.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system, comprising:
a first layer comprising one or more metal sub-layers; and
a protective overcoat (PO) layer adjacent to said first layer, the PO layer adapted to protect the first layer, a circuit logic at least partially embedded within said PO layer;
wherein the circuit logic couples to one of said metal sub-layers.

2. The system of claim 1, wherein the circuit logic comprises a dielectric layer abutting two electrode layers.

3. The system of claim 1, wherein a portion of the circuit logic abuts a surface of the PO layer and other portions of the circuit logic are embedded within multiple orifices in the PO layer.

4. The system of claim 1, wherein the PO layer comprises one or more materials selected from the group consisting of silicon oxynitride and silicon nitride.

5. The system of claim 1, wherein the PO layer has a thickness of approximately 2 micrometers.

6. The system of claim 1, wherein the circuit logic abuts one of a nitride sidewall or an oxide sidewall.

7. The system of claim 1, wherein the circuit logic comprises a passive component.

8. The system of claim 1, wherein the circuit logic comprises a capacitor.

9. The system of claim 1, wherein the circuit logic is adapted to couple to an electronic device by way of a wirebond or a bondpad.

10. The system of claim 1, wherein the system comprises a mobile communication device.

11. A method, comprising:
producing a circuit logic having a conductive layer, a substrate adjacent to one surface of the conductive layer, and a protective layer adjacent to another surface of the conductive layer, the another surface located opposite the one surface, the protective layer adapted to protect the conductive layer; and
at least partially embedding a circuit component within the protecting layer, the circuit component coupled to the conductive layer.

12. The method of claim 11, wherein embedding the circuit component comprises embedding a component that comprises a dielectric layer abutting two separate electrode layers.

13. The method of claim 11, wherein embedding the circuit component comprises embedding a circuit component such that a portion of the circuit component abuts a surface of the protective layer and other portions of the circuit component are embedded within multiple orifices in the protective layer.

14. The method of claim 11, wherein producing the circuit logic having the protective layer comprises producing a protective layer using at least one of silicon oxynitride and silicon nitride.

15. The method of claim 11, wherein producing the circuit component comprises producing a circuit component selected from the group consisting of a capacitor, an inductor and a resistor.

16. A method, comprising:
creating orifices within a protective overcoat layer of an integrated circuit, the protective overcoat layer adapted to protect the integrated circuit;
depositing a first electrode layer abutting the protective overcoat layer such that at least part of the first electrode layer is embedded within the protective overcoat layer;
depositing a dielectric layer abutting the first electrode layer such that at least part of the dielectric layer is embedded within the protective overcoat layer; and
depositing a second electrode layer abutting the dielectric layer such that at least part of the second electrode layer is embedded within the protective overcoat layer.

17. The method of claim 16, wherein depositing the first and second electrodes and the dielectric layer comprises forming a capacitor which is at least partially embedded within said protective overcoat layer.

18. The method of claim 16 further comprising incorporating said integrated circuit into a mobile communication device.

19. The method of claim 16 further comprising depositing a metal layer abutting the second electrode layer and coupling the metal layer to other metal layers within the integrated circuit.

20. The method of claim 19 further comprising coupling said other metal layers to other circuit logic using one of a bondpad or wirebond.

21. The method of claim 16 further comprising depositing an insulating sidewall layer abutting the dielectric layer, the protective overcoat layer and both electrode layers.
